(19) United States
(12) Patent Application Publication
(10) Pub. No.: US 2009/0310310 A1
(43) Pub. Date: Dec. 17, 2009

(54) Heat sink, electronic device, and method of manufacturing electronic device

(75) Inventor: Hisao Anzai, Kawasaki (JP)

Correspondence Address: STAAS & HALSEY LLP, SUITE 700, 1201 NEW YORK AVENUE, N.W., WASHINGTON, DC, 20005, US

(73) Assignee: FUJITSU LIMITED, Kawasaki (JP)

(21) Appl. No.: 12/461,620

(22) Filed: Aug. 18, 2009

Related U.S. Application Data
(63) Continuation of application No. PCT/JP07/55519, filed on Mar. 19, 2007.

(51) Int. Cl. H05K 7/20; B21D 53/02; F28F 7/00

(52) U.S. Cl. 361/704; 165/80.3; 29/890.03; 165/185

(57) ABSTRACT

A heat sink includes a base including a first surface and a second surface facing away from each other, the base being configured to have the first surface thermally connected to a heat generator; and multiple radiation fins extending from the second surface of the base, the radiation fins being reduced in length in accordance with a decrease in the temperature of the base due to the heat conducted from the heat generator, the radiation fins being shaped to bend outward.

### CROSS-REFERENCE TO RELATED APPLICATION

The present application is a continuation application filed under 35 U.S.C. 111(a) claiming benefit under 35 U.S.C. 120 and 365(c) of PCT International Application No. PCT/JP2007/055519, filed on Mar. 19, 2007, the entire contents of which are incorporated herein by reference.

### FIELD

A certain aspect of the embodiment discussed herein is related to a heat sink, an electronic device, and a method of manufacturing the electronic device.

### BACKGROUND

In recent times, electronic devices such as power devices have become higher in density and output so as to tend to generate larger amounts of heat. Therefore, these electronic devices that generate heat are provided with a heat sink for cooling. Usually, such heat sinks include multiple radiation fins provided on a base thermally coupled to an electronic element that serves as a heat generator.

Radiation fin structures are known that are described in, for example, Japanese Laid-open Patent Publications No. 2006-108239 and No. 2003-008264. FIG. 1 and FIG. 2 are schematic diagrams illustrating the heat sinks described in Japanese Laid-open Patent Publications No. 2006-108239 and No. 2003-008264, respectively.

Referring to FIG. 1 and FIG. 2, a heat sink 1A and a heat sink 1B include multiple radiation fins 3A and 3B, respectively, formed on a base 2 thermally coupled to an electronic element 5 serving as a heat generator. By thus providing the multiple radiation fins 3A and 3B, the radiation area of the radiation fins 3A as a whole and the radiation area of the radiation fins 3B as a whole are increased, thus resulting in greater efficiency of radiation of heat.

In the conditions illustrated in FIG. 1 and FIG. 2, cooling air that cools the heat sinks 1A and 1B is sent in a direction perpendicular to the plane of the paper of FIG. 1 and FIG. 2.

Here, referring to FIG. 1, the radiation fins 3A of the heat sink 1A are equal in length. Since the radiation fins 3A are equal in length, the heat sink 1A has a substantially rectangular parallelepiped shape. As a result, this heat sink 1A has high space efficiency, and therefore has been widely used.

On the other hand, in the heat sink 1B illustrated in FIG. 2, the radiation fins 3B are longest at the center of the base 2, and decrease in length from the center as they approach each side of the base 2.

FIG. 3 illustrates a temperature distribution in the base 2. In FIG. 3, A1, A2, and A3 correspond to the positions A1, A2, and A3, respectively, in the base 2 illustrated in FIG. 2.

As illustrated in FIG. 3, the temperature (T) is highest at the position A2, where the electronic element 5 serving as a heat generator is provided, and decreases from the position A2 toward each side of the base 2.

By thus providing the radiation fins 3B so that the radiation fins 3B are longest for high radiation efficiency where the temperature of the base 2 is highest and are reduced in length toward each side of the base 2 with a decrease in its temperature, the heat sink 1B is configured to achieve high radiation efficiency without waste of material. Further, the lengths of the radiation fins 3B, which correspond to the temperature distribution of the base 2, are not unnecessarily large. Accordingly, it is possible to reduce material and weight.

### SUMMARY

According to one aspect of the embodiment, a heat sink includes a base including a first surface and a second surface facing away from each other, the base being configured to have the first surface thermally connected to a heat generator; and a plurality of radiation fins extending from the second surface of the base, the radiation fins being reduced in length in accordance with a decrease in a temperature of the base due to heat conducted from the heat generator, the radiation fins being shaped to bend outward.

According to an aspect of the embodiment, an electronic device includes an electronic element and a heat sink, the heat sink including a base including a first surface and a second surface facing away from each other, the base having the first surface thermally connected to the electronic element; and a plurality of radiation fins extending from the second surface of the base, the radiation fins being reduced in length in accordance with a decrease in a temperature of the base due to heat conducted from the electronic element, the radiation fins being shaped to bend outward.

According to an aspect of the embodiment, a method of manufacturing an electronic device includes forming a heat sink including a base and a plurality of radiation fins extending from the base, the radiation fins being reduced in length in accordance with a decrease in a temperature of the base due to heat conducted from an electronic element on which the heat sink is to be mounted, the electronic element serving as a heat generator, the radiation fins each being bent at an intermediate portion thereof to have a first part extending vertically from the base and a second part extending outward at a substantially right angle from the first part; attracting and attaching the second part of at least one of the radiation fins to a conveying unit and conveying the heat sink to a position above the electronic element by the conveying unit; and mounting the heat sink on the electronic element by the conveying unit.

The object and advantages of the embodiment will be realized and attained by means of the elements and combinations particularly pointed out in the claims.

It is to be understood that both the foregoing general description and the following detailed description are exemplary and explanatory and not restrictive of the invention, as claimed.

### BRIEF DESCRIPTION OF THE DRAWING(S)

FIG. 1 is a front view of a first example conventional heat sink;

FIG. 2 is a front view of a second example conventional heat sink;

FIG. 3 is a graph of the temperature distribution of the base of the heat sink;

FIG. 4 is a perspective view of an electronic (semiconductor) device including a heat sink according to an embodiment of the present invention;

FIG. 5 is a front view of the heat sink according to the embodiment of the present invention;

FIG. 6 is a front view of a first variation of the heat sink according to the embodiment of the present invention;

FIG. 7 is a front view of a second variation of the heat sink according to the embodiment of the present invention; and

FIG. 8 is a diagram for illustrating a method of manufacturing the electronic device according to the embodiment of the present invention.

### DESCRIPTION OF EMBODIMENT(S)

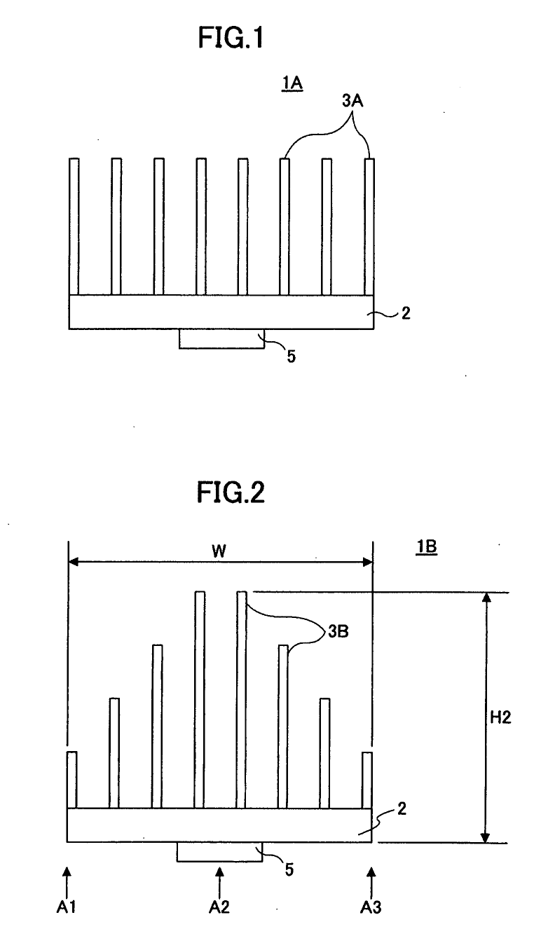

Generally, an electronic device is attached in an attachment space having a rectangular parallelepiped shape inside an electronic apparatus. Accordingly, the heat sink 1A having a rectangular parallelepiped overall shape as illustrated in FIG. 1 has good attachability to the electronic apparatus and high space efficiency with respect to the electronic apparatus.

However, in the case of making the radiation fins 3A uniform in length, the length of the radiation fins 3A is determined with reference to a maximum length at a position on the base 2 where its temperature is highest. Therefore, although having high space efficiency, the heat sink 1A illustrated in FIG. 1 is large in size because of the need for forming unnecessarily long radiation fins 3A as they approach each side of the base 2, thus having the problem of excess weight due to the need for a large amount of material.

On the other hand, the heat sink 1B illustrated in FIG. 2, which has high heat radiation efficiency as described above, has an inverted V shape in its front view. Therefore, an attachment space that fits the shape of the heat sink 1B is formed in an electronic apparatus where an electronic device with the heat sink 1B is provided. Accordingly, so-called dead space is likely to be formed in the electronic apparatus. Therefore, the heat sink 1B has the problem of reduction in space efficiency in attaching the heat sink 1B to the electronic apparatus due to its shape.

According to one aspect of the present invention, there are provided a heat sink that improves both space efficiency and heat radiation efficiency, an electronic device including the heat sink, and a method of manufacturing the electronic device.

A preferred embodiment of the present invention is explained below with reference to accompanying drawings.

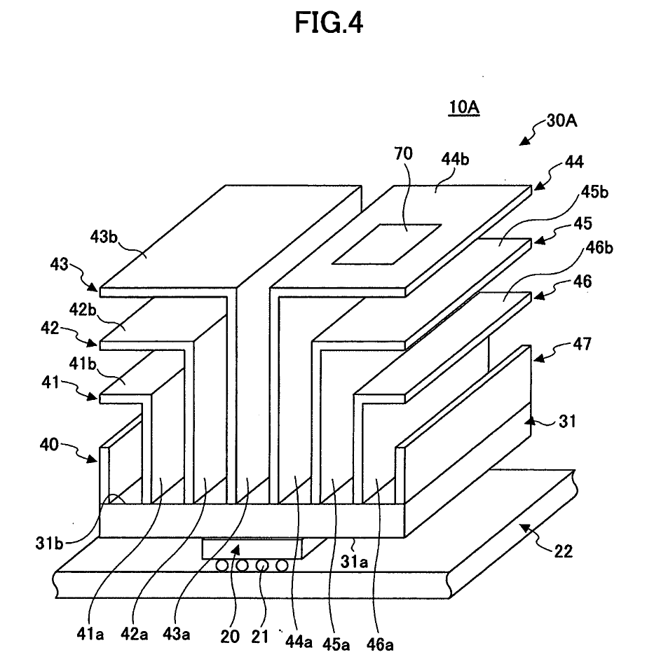

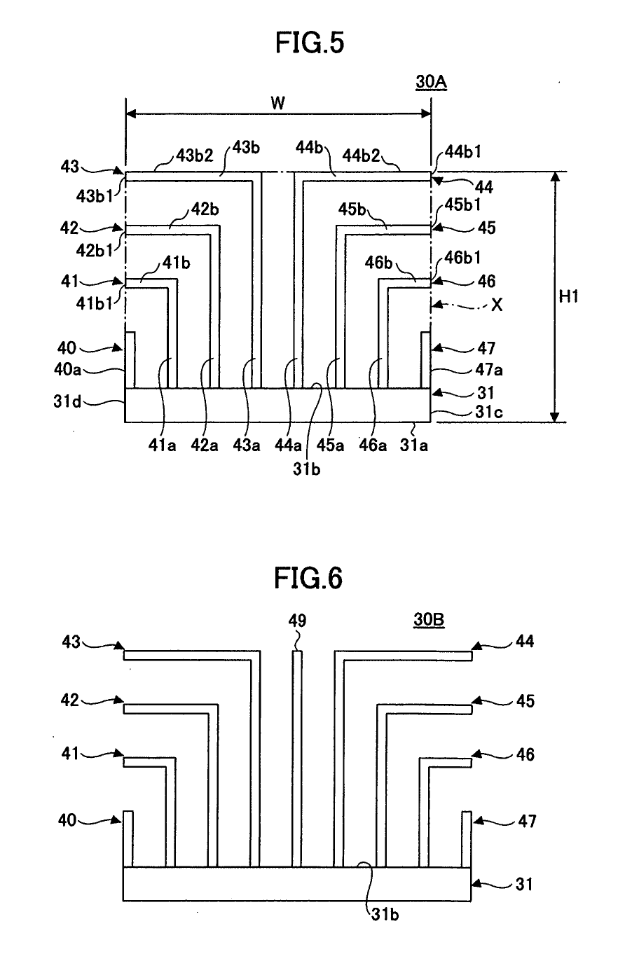

FIG. 4 is a perspective view of a semiconductor device 10A, which is an example of the electronic apparatus according to the embodiment of the present invention. FIG. 5 is a front view of a heat sink 30A according to the embodiment of the present invention.

First, a description is given of a configuration of the semiconductor device 10A. The semiconductor device 10A includes a semiconductor chip 20, a mounting board 22 such as a circuit board, and the heat sink 30A. The semiconductor chip 20 is an electronic element that generates heat, such as a high-frequency device or a power device.

The semiconductor chip 20 has multiple bumps 21 formed on its circuit-containing surface where a circuit is formed (lower surface in FIG. 4), and is joined to the mounting board 22 by flip-chip bonding. Accordingly, the semiconductor chip 20 is mounted on the mounting board 22 with its back surface (the surface on the side opposite to the circuit-containing surface) facing upward.

The heat sink 30A is fixed to the back surface of the semiconductor chip 20, for example, using an adhesive agent having high thermal conductivity. The method of fixing the heat sink 30A to the semiconductor chip 20 is not limited to this. For example, the heat sink 30A may be fixed to the semiconductor chip 20 through a thermal sheet.

Next, a description is given of a configuration of the heat sink 30A. The heat sink 30A includes a base 31 and multiple radiation fins, for example, eight radiation fins 40, 41, 42, 43, 44, 45, 46, and 47 in this embodiment. The heat sink 30A is formed of a material having high thermal conductivity, for example, a metal material having high thermal conductivity, such as aluminum. The base 31 and the radiation fins 40 through 47 may be formed as a unit. Alternatively, the radiation fins 40 through 47 may be joined to the base 31.

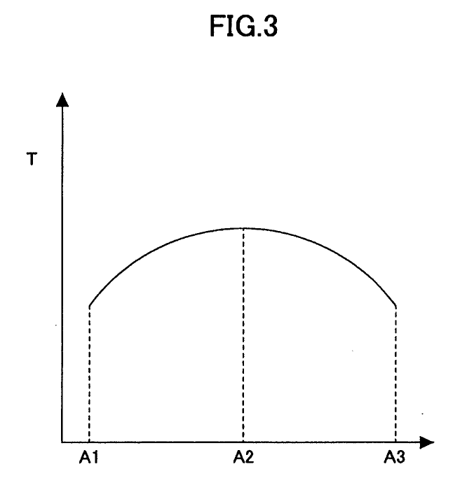

The base 31 has a flat plate shape, and has a lower surface (contact surface) 31a thereof thermally connected to the semiconductor chip 20. Further, according to this embodiment, the semiconductor chip 20 is thermally connected to the base 31 at its substantial center position. Accordingly, the temperature distribution of the semiconductor chip 20 at the time of its heat generation is substantially the same as the temperature distribution illustrated in FIG. 3.

The radiation fins 40 through 47 are formed to extend from an upper surface 31b of the base 31 on the side opposite to its surface to which the semiconductor chip 20 is connected. The lengths of the radiation fins 40 through 47 are determined so as to correspond to the temperature distribution illustrated in FIG. 3.

For example, the radiation fins 43 and 44, which are provided at the center part of the base 31 where the amount of the heat conducted from the semiconductor chip 20 is large (or the temperature of the base 31 is high), are long. As the amount of the heat conducted from the semiconductor chip 20 decreases in the base 31, the radiation fins 40 through 47 are reduced in length. That is, the radiation fins 40 through 47 are reduced in length toward each side from the center part of the base 31 (along the directions in which the radiation fins 40 through 47 are arranged). In other words, the radiation fins 40 through 47 are reduced in length as their respective positions at which the radiation fins 40 through 47 are provided on the base 31 are reduced in temperature.

It is assumed that the radiation fins 40 through 47 have respective lengths L₄₀ through L₄₇. Then, the lengths L₄₃ and L₄₄ of the radiation fins 43 and 44 positioned at the center are equal (L₄₃=L₄₄), and the lengths L₄₀ through L₄₂ of the radiations fins 40 through 42 positioned on the outer side of the radiation fin 43 and the lengths L₄₅ through L₄₇ of the radiations fins 45 through 47 positioned on the outer side of the radiation fin 44 are determined so that L₄₃>L₄₂>L₄₁>L₄₀ and L₄₄>L₄₅>L₄₆>L₄₇.

By thus providing the long radiation fins 43 and 44 having high radiation efficiency on a portion of the base 31 where the temperature is highest and reducing the radiation fins 40 through 42 and the radiation fins 45 through 47 in length in the outward directions in accordance with a decrease in the temperature, the heat sink 30A is achieved that has high radiation efficiency without waste of material or space. Further, the lengths of the radiation fins 40 through 47 correspond to the temperature distribution of the base 31, and are not unnecessarily large. Accordingly, it is possible to reduce material and weight.

Further, according to the heat sink 30A of this embodiment, of the radiation fins 40 through 47, the radiation fins 41 through 46 are bent outward. For example, according to this embodiment, the radiation fins 41 through 46 are bent outward at a substantially right angle at their intermediate portions, so that the radiations fins 41 through 46 include respective upright parts 41a through 46a, which stand perpendicular to the base 31, and respective horizontal parts 41b through 46b extending outward at a substantially right angle (laterally) from the corresponding upright parts 41a through 46a. By thus forming the upright parts 41a through 46a and the horizontal parts 41b through 46b, the radiation fins 41 through 46 each have an inverted L-letter shape. The radiation fins 40 and 47 stand perpendicular to the base 31.

According to this embodiment, the radiation fins 41 through 46 each having a flat plate shape may be formed on the base 31 and thereafter bent by press working, thereby forming the upright parts 41a through 46a and the horizontal parts 41b through 46b of the radiation fins 41 through 46. Alternatively, the radiation fins 41 through 46 including the upright parts 41a through 46a and the horizontal parts 41b through 46b, respectively, may be preformed by other methods such as casting and machining and joined to the base 31.

Here, attention is given to the positions at which the radiation fins 41 through 46 are bent. According to this embodiment, the upright parts 41a through 46a and the horizontal parts 41b through 46b are formed in the radiation fins 41 through 46, respectively. As a result, in a view from a direction from which cooling air flows, that is, in the front view illustrated in FIG. 5, the heat sink 30A has a rectangular external shape.

Here, as illustrated in FIG. 5, the external shape of the heat sink 30A is defined by the lower surface (contact surface) 31a and side surfaces 31c and 31d of the base 31; outside surfaces 40a and 47a of the radiations fins 40 and 47, respectively; end faces 41b1 through 46b1 of the horizontal parts 41b through 46b, respectively; and upper surfaces 43b2 and 44b2 of the horizontal parts 43b and 44b, respectively. The outline of the external shape of the heat sink 30A is indicated (supplemented) by a one-dot chain line X in FIG. 5.

For example, referring to FIG. 5, the left side surface 31d of the base 31, the outside surface 40a of the radiation fin 40, and the end faces 41b1 through 43b1 of the horizontal parts 41b through 43b are positioned in the same plane. Further, the right side surface 31c of the base 31, the outside surface 47a of the radiation fin 47, and the end faces 44b1 through 46b1 of the horizontal parts 44b through 46b are positioned in the same plane. Further, the upper surfaces 43b2 and 44b2 of the horizontal parts 43b and 44b are positioned in the same plane.

As a result, in the front view of the heat sink 30A (FIG. 5), the heat sink 30A has a rectangular external shape. As a result of thus having a rectangular external shape in a front (two-dimensional) view, the heat sink 30A has a rectangular parallelepiped overall (three-dimensional) shape as illustrated in FIG. 4.

As described above, generally, it is often the case that the space for attaching the semiconductor device 10A including the heat sink 30A has a rectangular parallelepiped shape in the electronic apparatus to which the semiconductor device 10A is attached. Accordingly, by forming the heat sink 30A into a rectangular parallelepiped overall shape according to the configuration of this embodiment, the semiconductor device 10A including the heat sink 30A has good attachability to the electronic apparatus and high space efficiency with respect to the electronic apparatus.

For example, it is assumed that the radiation conditions, the number of radiation fins, the amount of heat generation of the heat generator (the electronic element 5/the semiconductor chip 20), and the material of the heat sink are common to the above-described heat sink 1B illustrated in FIG. 2 and the heat sink 30A according to this embodiment.

In this case, the heat sink 1B has a height H2 as indicated by a vertical double-headed arrow in FIG. 2, while the heat sink 30A has a height H1 as indicated by a vertical double-headed arrow in FIG. 5, which is less than H2 because the radiation fins 41 through 46 are bent. Here, comparing the height H1 and the height H2, the height H2 is greater than the height H1 (H1<H2). Further, the heat sink 1B and the heat sink 30A have substantially the same width (horizontal dimension) W (indicated by a horizontal double-headed arrow in FIG. 2 and FIG. 5). Therefore, the heat sink 30A according to this embodiment maintains high radiation efficiency while being smaller in size than the heat sink 1B.

Further, as described above, it is often the case that the space for attaching the semiconductor device 10A has a rectangular parallelepiped shape in the electronic apparatus to which the semiconductor device 10A is attached. Accordingly, by forming the heat sink 30A into a rectangular parallelepiped overall shape as in this embodiment, it is possible to increase space efficiency with respect to the electronic apparatus and to prevent generation of so-called dead space inside the electronic apparatus, so that it is possible to contribute to the downsizing of the electronic apparatus.

As described above, according to the heat sink 30A of this embodiment, the radiation fins 40 through 47 have respective suitable lengths for radiating heat from the semiconductor chip 20. Accordingly, it is possible to increase radiation efficiency while reducing size. Further, since the radiation fins 41 through 46 are shaped to bend outward, it is possible to adjust the overall shape of the heat sink 30A by suitably determining the positions at which the radiation fins 41 through 46 are bent. Further, by having a rectangular parallelepiped overall shape as in this embodiment, the heat sink 30A is easily adaptable to the shape of the attachment space in the electronic apparatus. Thus, according to the heat sink 30A of this embodiment, it is possible to improve both radiation efficiency and space efficiency at the same time.

Further, according to this embodiment, the radiation fins 41 through 47 have their respective horizontal parts 41b through 47b. As a result, the horizontal parts 43b and 44b of the radiation fins 43 and 44 provided at the center of the base 31 form a relatively large plane in a plan view of the heat sink 30A although there is a groove or gap between the horizontal parts 43b and 44b. Therefore, according to this embodiment, the horizontal part 44b includes an information display part 70 (FIG. 4).

The information display part 70 may be, for example, a sticker printed with information such as the product information of the semiconductor device 10A, which is affixed to the horizontal part 44b. Usually, in the semiconductor device having the heat sink 1A (FIG. 1) or 1B (FIG. 2), this type of product information cannot be provided on its upper surface and is thus provided on a side surface or the bottom surface of the electronic element 5, so that there is the problem of poor visibility.

On the other hand, according to this embodiment, although the semiconductor device 10A includes the heat sink 30A, the presence of the horizontal parts 43b and 44b at the top of the heat sink 30A makes it possible to provide the information display part 70. Accordingly, it is possible to view the information display part 70 in a plan view of the semiconductor device 10A, so that it is possible to improve the visibility of information related to the semiconductor device 10A.

In this embodiment, not all of the radiation fins 40 through 47 are bent. That is, the radiation fins 41 through 46 are bent, and the radiation fins 40 and 47 provided at corresponding ends of the base 31 are not bent, or formed of upright parts without horizontal parts.

This is because the outside surface 40a of the radiation fin 40 and the side surface 31d of the base 31 are in the same plane and the outside surface 47a of the radiation fin 47 and the side surface 31c of the base 31 are in the same plane as illustrated in FIG. 5. If there is room on the base 31, the radiation fins 40 and 47 may be formed to have respective horizontal parts. Further, in the configuration illustrated in FIG. 4 and FIG. 5, it is also possible to provide the radiation fins 40 and 47 with respective horizontal parts extending inward.

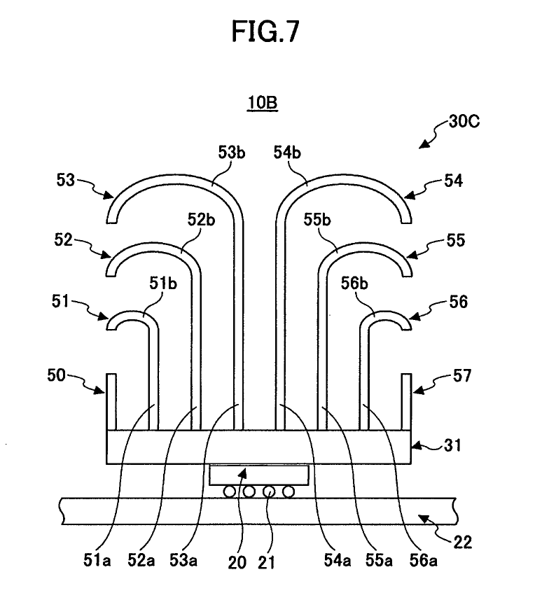

FIG. 6 is a diagram illustrating a variation of the heat sink 30A according to this embodiment. FIG. 7 is a diagram illustrating a variation of the semiconductor device 10A and the heat sink 30A according to this embodiment. In FIG. 6 and FIG. 7, the same elements as those illustrated in FIG. 4 and FIG. 5 are referred to by the same reference numerals, and a description thereof is omitted.

A heat sink 30B illustrated in FIG. 6 includes a center (radiation) fin 49 at the center of the base 31. The center fin 49 may not have a horizontal part as illustrated in FIG. 6. If the base 31 has space (room) for providing an odd number of radiation fins (nine in this variation) on its upper surface 31b as illustrated in FIG. 6, the center fin 49 is formed at the center position on the upper surface 31b (in the directions in which the radiation fins 40 through 47 and 49 are arranged).

The center fin 49 may be without a horizontal part as illustrated in FIG. 6 in order to form the heat sink 30B into a rectangular parallelepiped overall shape. By providing the center fin 49, it is possible to further improve the radiation efficiency of the heat sink 30B as a whole compared with the case of not providing the center fin 49.

Referring to FIG. 7, a semiconductor 10B includes a heat sink 30C including radiation fins 50, 51, 52, 53, 54, 55, 56, and 57. The radiation fins 51 through 56 include respective upright parts 51a through 56a and respective curved parts 51b through 56b extending outward from the corresponding upright parts 51a through 56a in a curved manner.

In the heat sink 30A described above with reference to FIG. 4 and FIG. 5, the horizontal parts 41b through 46b extend outward horizontally from the upright parts 41a through 46a. However, the shape of the extending part extending outward (or inward) from the upright part is not limited to a horizontal (or straight) shape, and may be curved like the curved parts 51b through 56b in this variation. According to this configuration, each of the radiation fins 51 through 56 has an inverted J-letter shape in a front view of the heat sink 30C (FIG. 7).

The shape of the extending part extending outward (or inward) from the upright part may be changed suitably in accordance with the length of the radiation fin or the size of the attachment space for attaching the heat sink.

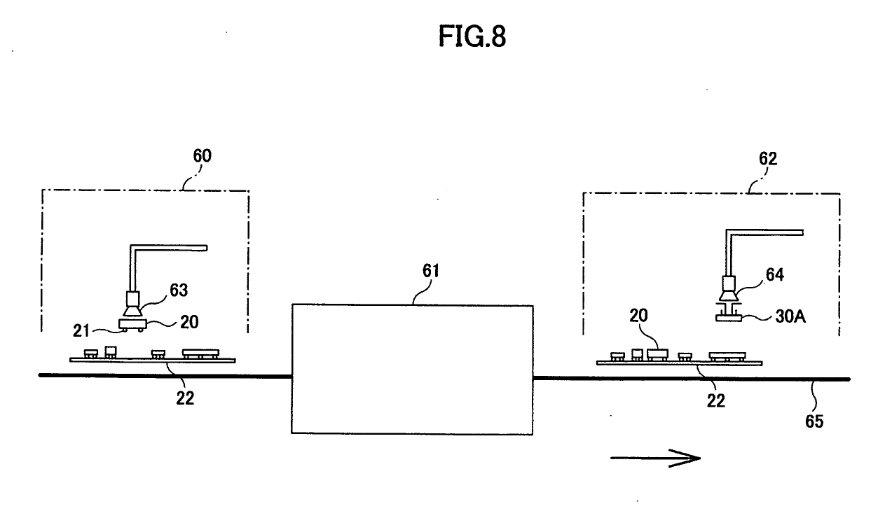

Next, a description is given, with reference to FIG. 8, of a method of manufacturing the semiconductor device 10A illustrated in FIG. 4.

In FIG. 8, the same elements as those illustrated in FIG. 4 and FIG. 5 are referred to by the same reference numerals, and a description thereof is omitted. Further, in the following description of the manufacturing process, a description is omitted of processes other than a chip mounting process for mounting the semiconductor chip 20 on the mounting board 22 and a mounting process for mounting the heat sink 30A on the semiconductor chip 20.

FIG. 8 is a diagram illustrating a manufacturing line for manufacturing the semiconductor device 10A. The mounting board 22 on which the semiconductor chip 20 is to be mounted is conveyed by a conveyor 65 in a direction indicated by an arrow in FIG. 8. Further, the manufacturing line illustrated in FIG. 8 includes a chip mounter 60, a reflow furnace 61, and a heat sink mounter 62, which are provided in this order in the direction indicated by the arrow in FIG. 8.

The chip mounter 60 includes a collet 63. The collet 63 attracts the semiconductor chip 20 to have it attached to the collet 63, and conveys the semiconductor chip 20 to a position over a predetermined mounting position on the mounting board 22. Then, the collet 63 moves downward to mount the semiconductor chip 20 on the mounting board 22 in a face-down manner. At this point, the semiconductor chip 20 is fixed, not permanently with the bumps 21 but temporarily, to the mounting board 22. The chip mounter 60 also mounts electronic components other than the semiconductor chip 20 on the mounting board 22.

After the semiconductor chip 20 and other electronic components are mounted on the mounting board 22 as described above, the mounting board 22 is conveyed by the conveyor 65 to be attached inside the reflow furnace 61. The reflow furnace 61 is for heating. As a result of the heating, the bumps 21, which are formed of solder or other suitable material, melt, so that the semiconductor chip 20 is soldered to the mounting board 22. Further, the other electronic components are also soldered to the mounting board 22 in the same manner. As a result, the semiconductor chip 20 and other electronic components are permanently fixed to the mounting board 22.

After completion of the heating in the reflow furnace 61, the mounting board 22 is cooled and conveyed to the heat sink mounter 62 by the conveyor 65. The heat sink mounter 62 mounts the heat sink 30A on the semiconductor chip 20.

For example, the heat sink mounter 62 includes a conveying unit 64. While being retained by the conveying unit 64, the heat sink 30A is conveyed to a position over the back surface of the semiconductor chip 20. Then, the heat sink mounter 62 lowers the conveying unit 64. An adhesive agent having high thermal conductivity (not graphically illustrated) is applied on the back surface (where the heat sink 30A is to be mounted) of the semiconductor chip 20. Accordingly, the heat sink 30A is mounted on the semiconductor chip 20 through the adhesive agent.

Like the collet 63, the conveying unit 64 has an attraction and attachment surface at its end, so that the heat sink 30A is attracted and attached (adhered) to the conveying unit 64 to be retained by the conveying unit 64. As described above, the heat sink 30A has the horizontal parts 43b and 44b at its top. This allows the conveying unit 64 to attract and attach the horizontal parts 43b and 44b to its attraction and attachment surface by vacuum suction. As a result, it is possible to convey the heat sink 30A with the conveying unit 64.

On the other hand, the heat sinks 1A and 1B illustrated in FIG. 1 and FIG. 2, respectively, have their respective radiation fins 3A and 3B extending upward. This prevents the heat sinks 1A and 1B from being subjected to vacuum suction. Accordingly, the heat sinks 1A and 1B are held by their sides, which causes their assembling efficiency to be reduced.

According to the manufacturing method of this embodiment, like the semiconductor chip 20, the heat sink 30A may be attracted from above and attached to the conveying unit 64, and be conveyed while being attached to the conveying unit 64 to be mounted on the semiconductor chip 20 as described above. This makes it easier to convey the heat sink 30A so that the semiconductor device 10A is manufactured with higher efficiency than conventionally.

Thus, according to one aspect of the present invention, a long radiation fin is provided where the amount of the heat conducted from a heat generator (heat generating body) is large, and radiation fins provided are reduced in length as the amount of the conducted heat decreases from the large amount. As a result, the radiation fins have respective suitable lengths for radiating the heat conducted from the heat generator, so that it is possible to increase radiation efficiency while achieving reduction in size. Further, since the radiation fins may be shaped to bend outward, it is possible to adjust the overall shape of the heat sink. This makes it possible to adapt the overall shape of the heat sink to the shape of the space for attaching the heat sink, so that it is possible to increase space efficiency.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority or inferiority of the invention. Although the embodiment of the present inventions has been described in detail, it should be understood that various changes, substitutions, and alterations could be made hereto without departing from the spirit and scope of the invention. The present invention is applicable to a wide variety of heat sinks having radiation fins and electronic devices including such heat sinks.

What is claimed is:

1. A heat sink, comprising:
a base including a first surface and a second surface facing away from each other, the base being configured to have the first surface thermally connected to a heat generator; and
a plurality of radiation fins extending from the second surface of the base, the radiation fins being reduced in length in accordance with a decrease in a temperature of the base due to heat conducted from the heat generator, the radiation fins being shaped to bend outward.

2. The heat sink as claimed in claim 1, wherein the base and the radiation fins have a rectangular external shape in a view from a direction from which cooling air flows.

3. The heat sink as claimed in claim 1, wherein each of the radiation fins has an inverted J-letter shape.

4. The heat sink as claimed in claim 1, wherein each of the radiation fins has a first part and a second part, the first part extending vertically from the base, the second part extending outward at a substantially right angle from the first part.

5. The heat sink as claimed in claim 4, further comprising:
an information display part provided on the second part of one of the radiation fins.

6. The heat sink as claimed in claim 4, wherein each of the radiation fins has an inverted L-letter shape.

7. The heat sink as claimed in claim 1, further comprising:
a first additional radiation fin and a second additional radiation fin extending vertically from a first end and a second end, respectively, of the base in a direction in which the radiation fins are arranged.

8. An electronic device, comprising:
an electronic element; and
a heat sink,
the heat sink including
a base including a first surface and a second surface facing away from each other, the base having the first surface thermally connected to the electronic element; and
a plurality of radiation fins extending from the second surface of the base, the radiation fins being reduced in length in accordance with a decrease in a temperature of the base due to heat conducted from the electronic element, the radiation fins being shaped to bend outward.

9. The electronic device as claimed in claim 8, wherein the base and the radiation fins have a rectangular external shape in a view from a direction from which cooling air flows.

10. The electronic device as claimed in claim 8, wherein each of the radiation fins has an inverted J-letter shape.

11. The electronic device as claimed in claim 8, wherein each of the radiation fins has a first part and a second part, the first part extending vertically from the base, the second part extending outward at a substantially right angle from the first part.

12. The electronic device as claimed in claim 8, wherein the heat sink further includes an information display part provided on the second part of one of the radiation fins.

13. The electronic device as claimed in claim 8, wherein each of the radiation fins has an inverted L-letter shape.

14. The electronic device as claimed in claim 8, wherein the heat sink further includes a first additional radiation fin and a second additional radiation fin extending vertically from a first end and a second end, respectively, of the base in a direction in which the radiation fins are arranged.

15. A method of manufacturing an electronic device, comprising:
forming a heat sink including a base and a plurality of radiation fins extending from the base, the radiation fins being reduced in length in accordance with a decrease in a temperature of the base due to heat conducted from an electronic element on which the heat sink is to be mounted, the electronic element serving as a heat generator, the radiation fins being shaped to bend outward;
attracting and attaching the second part of at least one of the radiation fins to a conveying unit and conveying the heat sink to a position above the electronic element by the conveying unit; and
mounting the heat sink on the electronic element by the conveying unit.

16. The method as claimed in claim 15, wherein said forming includes bending the radiation fins at respective intermediate portions thereof so that the radiations fins have respective first parts extending vertically from the base and respective second parts extending outward at a substantially right angle from the corresponding first parts.

17. The method as claimed in claim 10, wherein the second part of the at least one of the radiation fins is attracted and attached to the conveying unit by vacuum suction.
